(19) United States
(12) Patent Application Publication
(10) Pub. No.: US 2022/0026777 A1
(43) Pub. Date: Jan. 27, 2022

(54) TUNABLE OPTICAL MICROCAVITY FOR MODULATION AND GENERATION OF SPECIFIC RADIATION

(71) Applicants: UNIWERSYTET WARSZAWSKI, Warszawa (PL); WOJSKOWA AKADEMIA TECHNICZNA IM. JAROSLAWA DABROWSKIEGO, Warszawa (PL)

(72) Inventors: Jacek Szczytko, Kwirynow (PL); Katarzyna Lekenta, Brwinow (PL); Barbara Pietka, Piaseczno (PL); Mateusz Krol, Zielonka (PL); Rafal Mirek, Szczecin (PL); Daniel Stephan, Warszawa (PL); Wiktor Piecek, Zaborow (PL); Rafal Mazur, Piszczac (PL); Przemyslaw Morawiak, Lask (PL)

(21) Appl. No.: 17/276,998

(22) PCT Filed: Sep. 17, 2019
(86) PCT No.: PCT/PL2019/050051

§ 371 Date: Mar. 17, 2021

(30) Foreign Application Priority Data
Sep. 17, 2018 (PL) P.427031

(51) Int. Cl. G02F 1/21; G02F 1/1335

(52) U.S. Cl. CPC G02F 1/216; G02F 1/133557

(57) ABSTRACT

The present invention relates to a tuneable optical microcavity, characterised in that it comprises electrodes (12) on substrates (11), wherein the electrodes are comprised in the structure of dielectric or metal mirrors (13), or each of the electrodes has at least one dielectric or metal minor (13) on it, or the electrodes are semitransparent metal minors (13), wherein the mirrors are preferably located at a separation being a multiple of ½ lambda, where lambda is the central wavelength of the cavity mode, the cavity between the mirrors being filled with material (15) that changes the effective refractive index under the influence of external fields, preferably such as electric, magnetic field, thermal and mechanical stress.

The present invention relates to a tuneable optical microcavity with liquid crystalline or other layer that changes the effective refractive index under the influence of physical fields, which can induce a spatial distribution of the state of polarization and the direction of propagation of radiation transmitted therethrough, emit and modulate radiation generated inside the microcavity in such a way that the radiation obtains a specific spatial distribution of propagation directions and a spatial distribution of the state of polarization, and enables a strong light-matter coupling to be achieved, including: efficient generation of polaritons, polariton lasing from a Bose-Einstein condensate, and phonon lasing.

An optical microcavity with a layer that changes the effective refractive index under the influence of physical fields, according to the present invention can be used for modulation or generation of specific electromagnetic radiation, as in accordance with the invention disclosed herein, its optical mode, i.e. the wavelength of the electromagnetic wave trapped in the cavity, can be tuned with physical fields, which fields (preferably electric fields) induce an anisotropic change of the effective refractive index (and consequently the propagation velocity) of the electromagnetic wave in a medium filling the cavity, preferably a mesogenic medium in the liquid crystalline or isotropic phase, or in another medium that changes the effective refractive index under the influence of physical fields. The change of the effective refractive index of the medium in a cavity can be triggered with a physical field induced inside the cavity, preferably an electric field, e.g., by applying a DC or AC voltage to the electrodes surrounding the medium, by applying an external magnetic field or by a temperature change of the medium inside the cavity. The resulting change of the refractive index in the cavity leads to an energy shift of a microcavity optical mode with one polarization with respect to an optical mode with another polarization, or of both polarizations at once, and as a result, the propagation direction of light reflected or transmitted through the cavity is changed and depends on the direction of rotation of circular polarization or on the spatial arrangement of the plane of linear polarization of radiation relative to the structure of the medium filling the microcavity and the direction of the physical field operating inside the cavity.

A light emitter, preferably such as an organic dye, a nanomaterial in the form of quantum dots or nanocrystals with colour centres, a light-emitting layered material, e.g., MoSe₂, a luminescent perovskite layer, can be placed in the microcavity. The emitter can be excited to emit light by optical or electrical stimulation. The light coming out of the microcavity can leave it only for energies and angles determined by the optical mode of the microcavity, while obtaining the properties described above, which in effect results in the direction of propagation of light emitted by the cavity being changed and dependent on the direction of rotation of circular polarization or the spatial arrangement of the plane of linear polarization of radiation relative to the structure of the microcavity filling medium and the direction of the physical field operating inside the cavity.

If the energies of the electromagnetic wave of the cavity optical mode and the light emitter are close to each other, a so-called strong light-matter coupling occurs, resulting in new quasi-particles, so called exciton polaritons, emerging in the microcavity. Under conditions when the cavity optical mode is matched, a strong excitation of the emitter by means of pulsed or continuous light or by injection of electric charges can lead to the Bose-Einstein condensation of exciton polaritons and the appearance of polariton lasing. In the present invention, the emitter in the cavity should be preferably located at a place where the electric field strength of the wave optical mode is at its maximum. This is confirmed by numerical calculations, allowing to analyze the distribution of the electric field in space and performed by the present inventors with the transfer matrix method for an electromagnetic wave propagating in the cavity described herein. The emitter in the form of a thin layer, nanoparticles, a dye or quantum well can preferably, according to the invention, be located on the surface of a mirror or at a suitable distance from it. The emitters in the form of colour centres or nanoparticles/quantum dots can be located in the entire volume of the microcavity.

The polariton lasing occurs at a lower excitation threshold than the photon lasing, which allows for construction of devices with a higher conversion efficiency of the energy supplied into the energy of emitted radiation.

Specific radiation emitted from the microcavity can be used in telecommunications and information processing, including as a source for emission of radiation for the transmission of encoded information, specifically a one-time key, as an element enabling replication of emission channels of an information bearing signal or a component of logic elements such as a logic gate operating based on interaction of light beam/beams (generally electromagnetic radiation) with the structure in the cavity. The subject of the invention can be used, inter alia, in devices such as light polarization analyzers, in polarization control of light from photon or polariton lasing, induction and control of Bose-Einstein condensates, logic systems.

Solutions providing for tuning optical microcavities by changing the cavity thickness in the form of a wedge, e.g., the thickness obtained during the microcavity formation (e.g., during the semiconductor growth) are known from the prior art [C. Weisbuch, M. Nishioka, A. Ishikawa, Y. Arakawa, Observation of the coupled exciton-photon mode splitting in a semiconductor quantum microcavity, Phys. Rev. Lett. 69, 3314-3317 (1992); M. S. Skolnick, T. A. Fisher, D. M. Whittaker, Strong coupling phenomena in quantum microcavity structures. Semicond. Sci. Technol. 13, 645-669 (1998); J. Kasprzak, et al., Bose-Einstein condensation of exciton polaritons. Nature 443, 409 (2006)]. Later, the idea of a variable microcavity thickness has been commonly adopted in applications using semiconductor materials and structures, wherein the tuning of the optical mode is dependent on the position on the sample. Another solution is to change separation between dielectric mirrors using piezo-positioners [S. Dufferwiel et al., Valley-addressable polaritons in atomically thin semiconductors, Nat. Phot. 11, 497-501 (2017); S. Dufferwiel, S. Schwarz, F. Withers, A. A. P. Trichet, F. Li, M. Sich, O. Del Pozo-Zamudio, C. Clark, A. Nalitov, D. D. Solnyshkov, G. Malpuech, K. S. Novoselov, J. M. Smith, M. S. Skolnick, D. N. Krizhanovskii, A. I. Tartakovskii, Exciton-polaritons in van der Waals heterostructures embedded in tunable microcavities, Nat. Commun. 6, 8579 (2015)], by adjusting the position of the upper concave mirror to the planar mirror constituting the lower part of the cavity [S. Schwarz, S. Dufferwiel, P. M. Walker et al., Two-dimensional metal-chalcogenide films in tunable optical microcavities, Nano Lett. 14, 7003-7008 (2014)], or by pressing two dielectric mirrors to each other (work conducted by the present inventors).

Also known are cavities of the Fabry-Perot interferometer type with a liquid crystalline layer allowing for tuning the optical mode, used as a tuneable optical filter or as a light valve operating for a limited wavelength range (work conducted by the present inventors: W. Piecek, L. R. Jaroszewicz, E. Miszczyk, Z. Raszewski, M. Mrukiewicz, P. Perkowski, E. Nowinowski-Kruszelnicki, J. Zieliński, M. Olifierczuk, J. Kgdzierski, X. W. Sun, K. Garbat, K. Kowiorski, P. Morawiak, R. Mazur, J. Tkaczyk, Refractive index matched half-wave plate with a nematic liquid crystal for three-dimensional laser metrology applications, Opto-electronics Rev., 24, 169-182 (2016); L. R. Jaroszewicz, Z. Raszewski, W. Piecek, P. Perkowski, E. Nowinowski, Liquid Crystal Light Modulators, Bel Studio Sp z o. o., Warsaw, 2014, products form Computational Physics, Inc, USA, Scientific Solutions, USA, and from others, as well as patent documents U.S. Pat. Nos. 4,779,959A, 5,321,539A, 5,293,272A).

There are known solutions based on the use of liquid crystals as optical converters for changing the phase or direction of the optical beam (e.g., commercially available liquid crystal retarder marketed by Meadowlark, q-plate [L. Marrucci, C. Manzo, D. Paparo, Optical spin-to-orbital angular momentum conversion in inhomogeneous anisotropic media, Phys. Rev. Lett. 96, 163905 (2006)], and many, many others). These types of analyzers and/or light converters do not spatially separate beams with different light polarizations.

Laser systems using cholesteric liquid crystals are known in the prior art [H. Coles, S. Morris, Liquid-crystal lasers, Nat. Phot. 4, 676 (2010); M. A. Matranga, M. P. De Santo, G. Petriashvili, A. Chanishvili, G. Chilaya, and R. Barberi, Frequency tunable lasing in a three layer cholesteric liquid crystal cell, Ferroelectrics 395, 1-11 (2010); T.-H. Lin, Y.-J. Chen, C.-H. Wu, A. Y.-G. Fuh, J.-H. Liu, and P.-C. Yang, Cholesteric liquid crystal laser with wide tuning capability, Appl. Phys. Lett. 86, 161120 (2005)]. The selective reflection phenomenon in chiral liquid crystal compounds was used in work on liquid crystal lasers, where the periodic structure of a liquid crystal in the cholestric, smectic or so-called blue phase (blue phase type I, or II, or III) forms a resonance cavity [H. Coles, S. Morris, Liquid-crystal lasers, Nat. Phot., 4, 676 (2010)]. The emitter in this solution is a dye that is dispersed in a liquid crystal matrix, an emitting nanomaterial or an emission centre being a part of the liquid crystal molecule. Liquid crystal lasers are usually pumped with an external pulse laser with tuneable wavelength. Changing the wavelength of the pumping laser results in a change in the energetic position of the forbidden photonic gap of the chiral liquid crystal. A shift of the forbidden band gap edge makes it possible to match the edge energy with the transition energy in the dye, which in turn allows for observation of the emission gain.

Semiconductor-based optical microcavities (e.g., GaAs) are known, in which photon and polariton lasing were obtained, in particular the state of so-called Bose-Einstein condensate was achieved [J. Kasprzak et al., Bose-Einstein condensation of exciton polaritons, Nature 443, 409 (2006)]. For semiconductor microcavities the condensate has been obtained at cryogenic (GaAs, CdTe) and at room temperature (GaN [R. Butté et al., Room-temperature polariton luminescence from a bulk GaN microcavity, Phys. Rev. B 73, 033315 (2006); S. Christopoulos et al., Room-temperature polariton lasing in semiconductor microcavities, Phys. Rev. Lett. 98, 126405 (2007); J. J. Baumberg et al., Spontaneous polarization buildup in a room—temperature polariton laser, Phys. Rev. Lett. 101, 136409 (2008)], ZnO [Y.-Y. Lai, Y.-P. Lan, T.-C. Lu, Light: Science & Applications 2, 76 (2013)]). Microcavities filled with organic materials in which photon and polariton lasing at room temperature have been obtained are known [K. S. Daskalakis, S. A. Maier, R. Murray, S. Kéna-Cohen, Nonlinear interactions in an organic polariton condensate, Nat. Mater. 13, 271 (2014); R. J. Holmes, S. R. Forrest, Strong exciton-photon coupling and exciton hybridization in a thermally evaporated polycrystalline film of an organic small molecule, Phys. Rev. Lett. 93, 186404 (2004)]. A disadvantage of such systems is the lack of control over the state of light polarization, as the TE and TM modes depend only on the geometry of the cavity, which cannot be changed after the cavity is assembled.

US2018066930 (A1) patent application relates to a Fabry-Perot cavity, manufacturing method thereof, interferometer and measuring method for wavelength of light. The Fabry-Perot cavity includes two parallel substrates and a liquid crystalline layer between the two parallel substrates. Light can be transmitted through the first substrate and subsequently through the second substrate via the liquid crystalline layer, and a deflection angle of the director of molecules of the liquid crystalline layer (and thus the optical axis of the anisotropic medium, which is the liquid crystalline layer) can be changed by applying various voltages between the two substrates.

US2017276996 (A1) patent application comprises spatial filter arrays including an array of liquid crystal (LC) microcavities. The microcavities are defined by two reflectors and an LC layer situated between them. The tunable filter is secured to an image sensor array so that the liquid crystal microcavities are coupled to respective photodetectors of the image sensor array. Patterned electrodes are situated about the LC layer to tune the microcavities.

US2017/0199036 A1 patent application discloses devices that allow to obtain quasi-particles in the Bose-Einstein condensate state at room temperature in microcavities with Bragg reflectors. EP 0 795 941 A1 patent application discloses an optoelectronic semiconductor device comprising Bragg reflectors fabricated at least in part from an electrically conductive polymer material. US2016/0109760 A1 patent application reports, inter alia, microcavities filled with liquid crystalline materials, and a method for aligning liquid crystalline layers in microcavities with light. US2015/0071631 A1 patent application discloses a passive optical repeater that is operated in the Bose-Einstein condensate state obtained in an optical microcavity with Bragg reflectors.

The technical problem underlying the present invention is to obtain a source of specific electromagnetic radiation, preferably with the use of the Bose-Einstein condensation, by providing the tuning of the microcavity with physical fields in its entire volume, preferably by means of an electric field induced inside the cavity, by applying a DC or AC voltage, by applying an external magnetic field or by changing the temperature of the medium in the cavity.

The purpose of the present invention is to develop a system enabling an effective, and essentially dynamic, creation of conditions for strong light-matter coupling and dynamic control of polarization of light generated inside a liquid crystalline cavity, reflected and transmitted through the device by changing the direction of light depending on its circular or linear polarization.

As a result of intensive research, the inventors of the present invention have developed a liquid crystalline microcavity that unexpectedly solves the aforementioned technical problems.

### SUMMARY OF THE INVENTION

The present invention relates to a tuneable optical microcavity characterised in that it comprises electrodes on substrates, wherein the electrodes are comprised (included) in the structure of dielectric or metal mirrors, or each of the electrodes has at least one dielectric or metal mirror on it, or the electrodes are semitransparent metal mirrors, wherein the mirrors are preferably located at a separation being a multiple of ½ lambda, where lambda is the central wavelength of the cavity mode, the cavity between the mirrors being filled with material that changes the effective refractive index under the influence of external fields, preferably such as electric, magnetic field, thermal and mechanical stress.

Preferably, the electrodes are transparent for electromagnetic wave, preferably in the visible VIS and/or infrared IR and/or medium wavelength infrared MWIR ranges.

Preferably, the electrodes are made of such material as indium tin oxide, conductive polymer, metal, or a combination thereof.

Preferably, the mirrors are Bragg reflectors composed of multiple alternating layers of dielectrics with different refractive indices, and the optical thickness of the layers is ¼ lambda.

Preferably, the electrodes included in the structure of metal or dielectric mirrors or the dielectric or metal mirrors are located at a separation from ½ lambda to 20 lambda, lambda being the central wavelength of the cavity mode.

Preferably, the material filling the cavity that changes the effective refractive index under the influence of external fields is a liquid crystalline material in the isotropic phase, or in the nematic phase, or the cholesteric phase, or the blue phase, or the smectic phase, particularly in the SmC* and SmC*A phases, or a polymeric composite material comprising a liquid crystal, and/or a luminophore, and/or a dye, /or nanoparticles, /or proteins.

Preferably, the substrate can be transparent or non-transparent.

Preferably, the optical microcavity according to the invention has the form of a flat-parallel cell.

Preferably, an electromagnetic wave emitter is comprised inside the optical microcavity according to the invention, preferably on the surface of one or two mirrors, or dissolved or suspended in a material that fills the cell and changes the refractive index under the influence of physical fields, wherein the emitter emits an electromagnetic wave that matches the central wavelength of the cavity mode.

Preferably, the emitter of the electromagnetic wave is selected from such as MoSe₂, CdSe, WSe₂, luminescent perovskite, nanodiamond, dye, luminophore or proteins.

The operational principle of the cavity is based on the so called optical spin Hall effect (OSHE) that results from the mode splitting, i.e., the energy difference between the TE and TM modes of light propagating in the optical microcavity.

An optical microcavity is an area of space bounded on at least two sides by (metal or dielectric) mirrors, preferably so called Bragg reflectors. The Bragg reflectors are composed of multiple alternating layers of dielectrics with different refractive indices, and the so called optical thickness (i.e., the product of the optical path and the refractive index) of the layers is ¼ lambda. Lambda means the central wavelength of the cavity mode.

The thickness of the reported cavity, and thus the separation between the mirrors (preferably Bragg reflectors), is given by a multiple of ½ lambda, where lambda means the wavelength of an electromagnetic wave propagating in the medium filling the cavity. According to the invention, the cavity thickness ranges from ½ lambda to 20 lambda. The microcavity is filled with an optical material that changes the effective refractive index under the influence of external fields, preferably under the influence of an electric field, preferably with a liquid crystal, i.e., an anisotropic optical medium. It is also preferable to use materials exhibiting the Kerr effect or another effect to change the effective refractive index under the influence of physical fields. The change of the effective refractive index, preferably by inducing a change in the spatial alignment of the average alignment direction of long axes of the liquid crystal molecules (the so called director), and consequently of the orientation of the indicatrice axis (i.e., the refractive index ellipsoid), is implemented by applying a potential difference to the electrodes surrounding the medium (preferably a liquid crystal) in the cavity with the electrodes (preferably transparent, preferably made of tin indium oxide ITO), or preferably the electrodes being metallic mirrors. A change of the effective refractive index induced by a physical field, preferably an electric one, preferably by changing the orientation of the optical axis in a liquid crystal medium (or by changing the shape of the indicatrice for a medium exhibiting the Kerr effect or an analogous one, as it is the case for mesogenic materials in the isotropic phase), results in a change of both the optical path of the light beam or generally an electromagnetic wave, with the light vector in the perpendicular plane, as well as the light beam with the light vector in a plane parallel to the director plane of motion, thereby shifting the energy of the optical modes of the cavity (TE or TM mode or both). Due to the use of the optical spin Hall effect, the polarization of light transmitted through or reflected from the microcavity depends on the direction in space and the splitting energy of the TE and TM modes.

Due to the use of a medium that changes the refractive index under the influence of physical fields, preferably a liquid crystal, one can control the splitting in a broad energy range, thus obtaining various spatial patterns of the distribution of circular and linear polarizations.

### BRIEF DESCRIPTION OF THE DRAWINGS

FIG. 1 shows the structure of a tuneable optical microcavity for modulation and generation of specific radiation. 11—optical substrate, preferably made of quartz glass, 12—typical position of the electrode, preferably transparent, preferably made of tin indium oxide, 13—semitransparent mirrors, preferably Bragg reflectors, 14—layer aligning the liquid crystalline material, preferably polyimide or polyamide layer.

FIG. 2 shows a simplified schematic diagram of a measurement system used for investigation of the optical microcavity filled with material that changes the effective refractive index under the influence of physical fields according to the present invention.

FIG. 3 shows the dispersion of the real part of electric permittivity of a 1999C liquid crystalline material. The squares correspond to the perpendicular component ε_{⊥}(f), the diamonds correspond to the parallel component ε_{∥}(f) of the real part of the dielectric constant as a function of frequency of the alternating electric field acting on a 1999C (DFNLC) dual frequency liquid crystalline material, measured at 21° C., frequency at the intersection point f_{C}˜11 kHz.

FIG. 4 shows the energy position of the cavity mode for two perpendicular light polarizations and the Q-factor of the cavity as a function of voltage applied to the electrodes for a material with planar texture (HG).

FIG. 5 shows the dispersion dependence (the energy dependence on the light propagation angle for light coming out of the cavity) for a material with planar texture (HG).

FIG. 6 shows the angular distribution in x and y directions of the degree of sigma plus (positive values) and sigma minus (negative values) circular polarization for light transmitted through the microcavity for a material with planar texture (HG) directed at the angle of 45 degrees with respect to the TE and TM polarization axes.

FIG. 7 shows the energy position of the cavity mode for two perpendicular light polarizations and the Q-factor of the cavity as a function of voltage applied to the electrodes for a liquid crystalline material with homeotropic texture (HG).

FIG. 8 shows the dispersion dependence (the energy dependence on the light propagation angle for light coming out of the cavity) for a liquid crystal material with homeotropic texture (HG).

FIG. 9 shows a simulated distribution of electric field of 810 nm wavelength inside the microcavity filled with a liquid crystal with an emitter in the form of MoSe₂ monolayers deposited on the surface of one of the mirrors (in the 0 nm position).

FIG. 10 shows the emission intensity from a liquid crystalline microcavity with MoSe₂ monolayers as a function of voltage applied to electrodes of the structure.

FIG. 11 shows the luminescence spectrum from a +/−5 deg range from a cavity filled with a liquid crystal with HT texture, additionally doped with CdSe quantum dots for five different angles of rotation of the liquid crystal molecules from the growth axis: 0; 20; 30 and 40 degrees. The microcavity consists of two Bragg reflectors composed of 5 pairs of SiO₂/TiO₂ oxide layers each.

FIG. 12 shows the dependence of the refractive index n of CN liquid as a function of squared voltage U2 applied to the optical wedge filled with this liquid. The refractive index was determined based on the deviation of the direction of the laser beam propagation on a wedge filled with CN liquid. [Ewa Uliszewska, Diploma thesis “Badanie zjawiska odchylenia biegu promienia laserowego z wykorzystaniem efektu Kerra w klinie optycznym” (“A study on laser beam deflection using the Kerr effect in an optical wedge”) Military University of Technology, Faculty of New Technologies and Chemistry (WTC), 2015].

### DETAILED DESCRIPTION OF THE INVENTION

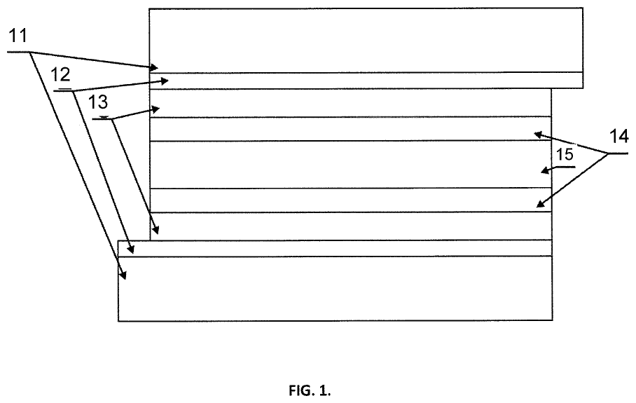

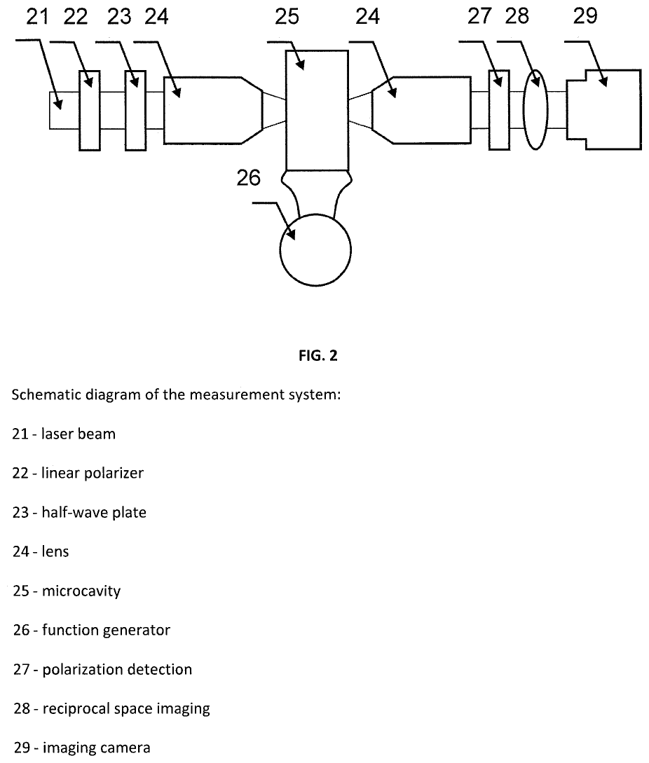

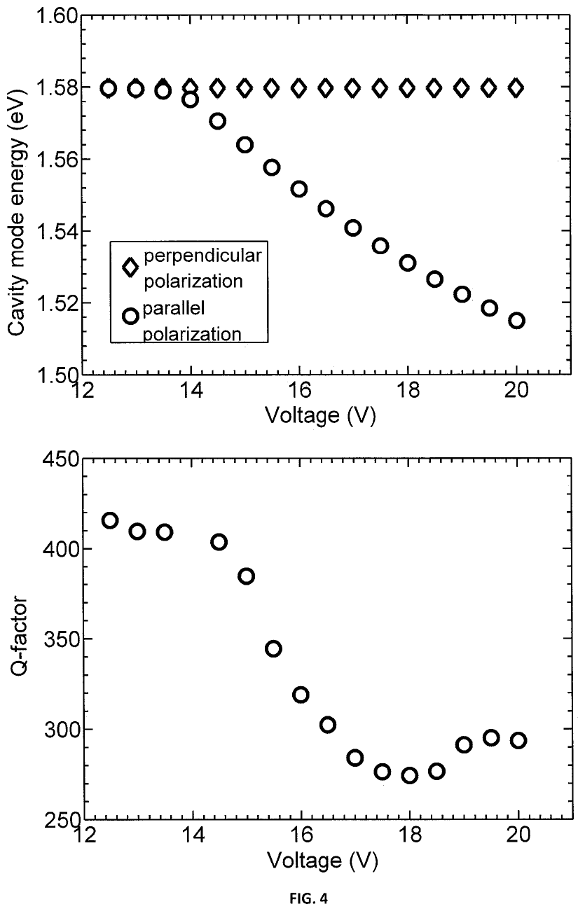

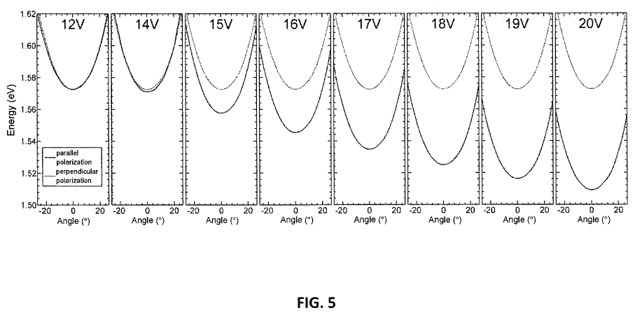

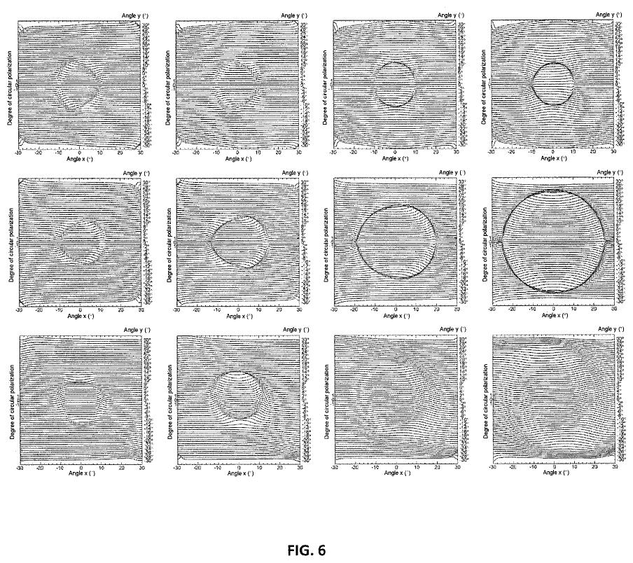

FIG. 1 shows schematically the structure of an optical microcavity filled with a liquid crystal in the nematic phase (15). The mirrors (13) are dielectric Bragg reflectors fabricated for the lambda wavelength. For specific implementation, the energy of the lambda wave is shown in FIG. 4. A liquid crystal (15) with planar texture (HG), with the director (and thus the direction of the optical axis) parallel to the cavity plane was used. Under the influence of the voltage applied to transparent electrodes (12), preferably made of indium tin oxide (ITO), the liquid crystal director, here with a positive anisotropy of dielectric permittivity (15) rotates, striving for a direction perpendicular to the plane of the cavity. Thus, the splitting of the TE and TM cavity modes decreases in line with the applied voltage, as shown in FIG. 4 illustrating the position of the mode minimum, and in FIG. 5 illustrating the full dispersion dependence (energy-angle) for the energy of light coming out of the microcavity. FIG. 6 shows the angular dependence of the degree of circular polarization for light coming out of the microcavity.

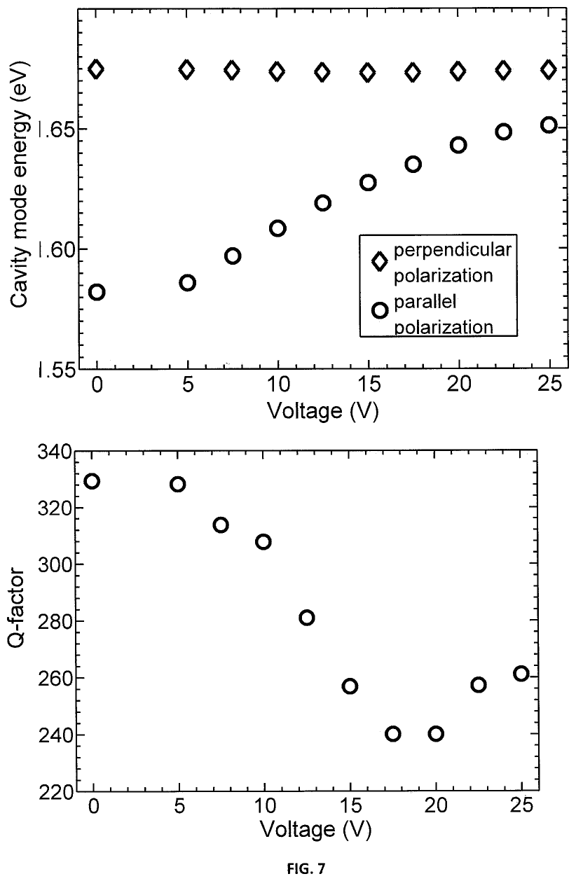

According to another embodiment, a liquid crystal (15) with homeotropic texture (HT), with the director (and thus the direction of optical axis) perpendicular to the cavity plane, is used in an optical microcavity schematically illustrated in FIG. 1, filled with the liquid crystal (15), wherein mirrors (13) are dielectric Bragg reflectors fabricated for the lambda wavelength. When voltage is applied to transparent electrodes (12), preferably fabricated from indium tin oxide (ITO), the director of the liquid crystal (15) rotates striving towards the direction lying in the cavity plane. Thus, the splitting of the TE and TM cavity modes increases due to the applied voltage, as shown in FIG. 7 illustrating the position of the mode minimum, and FIG. 8 illustrating the full energy-angle dispersion dependence for the energy of light coming out of the cavity.

In yet another embodiment of an optical microcavity illustrated in FIG. 1, filled with a liquid crystal (15), the mirrors (13) are semitransparent metallic mirrors that at the same time can be used as electrodes (12).

### EMBODIMENTS

### Example 1

A microcavity was assembled based on two quartz glass substrates (QP). In the illustrated example a JG3 quartz glass with dimensions 12.7 mm×25 mm and initial thickness 5 mm was used. The glass was mechanically polished for an optical flatness better than lamda/14 (the central wavelength lambda=633 nm). The final thickness of the substrates was about 4 mm. The flat-parallelism of the substrate surfaces was better than 2 arcsec. The substrates were ultrasonically washed and placed in a working chamber of a vacuum system for deposition of metallic and dielectric layers. A transparent electrode in the form of a 30 nm thick indium tin oxide (ITO) layer with refractive index n_{ITO}=1.890 (as measured for a wavelength Δ=632.8 nm) and specific resistance 100 Ohm/sq was deposited on a quartz substrate by vacuum evaporation in a controlled low-pressure oxygen atmosphere. The ITO deposition process was carried out at substrate temperature 200° C., at oxygen pressure of 7×10⁻⁵ mbar and with assistance of a XIAD ion source used to clean and degas the substrate surface, on which ITO was deposited and the ITO layer structure was formed.

A stack of dielectric layers was deposited on the surface of a transparent ITO electrode to form a so called Bragg reflector (DBR). In a specific embodiment, the reflector was composed of 6 pairs of TiO₂ layers of a high refractive index for an electromagnetic wave (n_{TiO2}=2.436 for lambda=0.6328 μm), deposited at 5×10⁻⁵ mbar oxygen pressure at temperature 250° C., and a SiO₂ layer of a low refractive index (n_{SiO2}=1.456 for lambda=0.6328 μm), deposited at 5×10⁻⁵ mbar oxygen, at temperature 200° C. During the deposition process of all layers a XIAD ion source was used for whipping the deposited layers with argon ions. The electrodes and DBR reflectors were finally shaped using suitably formed masks covering/uncovering areas of quartz substrates.

So prepared substrates were transferred to a spin coater where the DBR surface was spin coated with a PI solution (SE1211 polyimide from Nissan Chemicals, refractive index for lambda=633 nm, n_{PI}=1.54). Then, the polyimide layer was dried (at 70° C.) and polymerized at elevated temperature (about 180° C.). A so prepared PI layer was rubbed with a specialised device with a roller covered with dedicated technical textile. An about 60 nm thick polyimide layer was finally obtained.

The PI layer ensures an almost normal to surface (homeotropic—HT) orientation of the director of the liquid crystalline structure (i.e., normal to surface orientation of the optical axis of the liquid crystalline medium that fills the cavity), and thus a normal to surface orientation of the optical axis of the liquid crystalline medium which is not exposed to an electric or magnetic field.

The QP substrates prepared with the ITO electrode, the DBR mirror and the PI orienting layer were subsequently assembled with the DBR mirrors facing each other so as to obtain a flat-parallel cell for a liquid crystalline material between the surfaces with ITO, DBR and PI (FIG. 1). To ensure identical separation between the QP surfaces, a few micrometer thick (thermosetting) adhesive line was applied on edges of one of the substrates using a fluid dispenser. Before the adhesive was applied, glass microroller spacers with a nominal diameter 0.9 μm were added to the adhesive. The assembled cell was subsequently compressed so as to have the QP surfaces settled on the glass rollers thus forming a cell with flat-parallel boundary walls. The flat-parallelism of the cell was controlled during the compression process by observation of possible interference fringes (a D line from sodium lamp was used for cell illumination). After suitable cell parameters were obtained during the compression process (thickness, flat-parallelism), the adhesive was cured (by warming up the entire cell up to the polymerization temperature of the adhesive).

In the line formed by the adhesive with spacers, a small inlet was left for filling the cell with a liquid crystalline material. To fill the cell with a liquid crystalline material, the cell was placed in an oven that allowed to obtain a low vacuum. The cell was laid so that the cell to be filled was placed in the vicinity of a special technological sponge, saturated with a liquid crystalline material. Then, the oven was evacuated and heated up to a temperature by 20° C. exceeding the temperature of the liquid crystalline material transition to the isotropic phase. After the cell was held at the aforementioned temperature and the low vacuum was maintained for a suitable time, the cell was moved so that the inlet for filling the cell was brought into contact with the liquid crystalline material filling the sponge. After the liquid crystalline material was drawn by the capillary action into the cell, the oven was slowly cooled down and filled with air.

The inlet for filling was cleaned and sealed with a special technological adhesive to prevent the material from flowing out from the cell and to prevent the contact of the liquid crystalline material with air.

Using an ultrasonic soldering iron and a special alloy with a low melting point, power supply cables were soldered to the ITO electrodes. The cables and cell joints were strengthened with special adhesives.

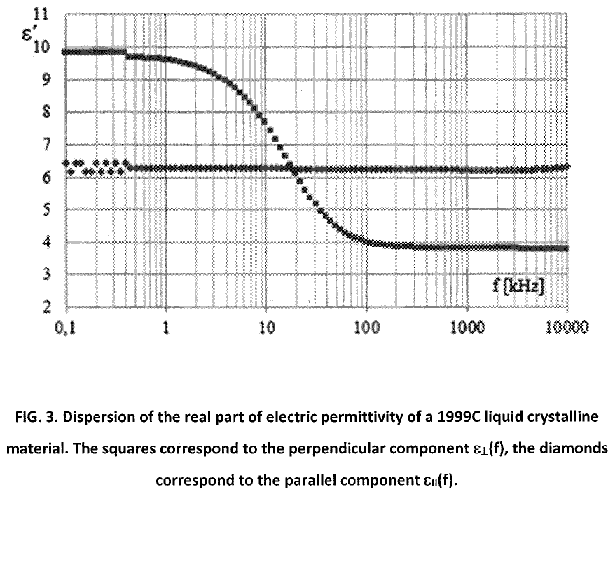

In the presented embodiment of microcavity, a liquid crystalline material labelled 1999C (marked herein as DFNLC), developed and produced at the Military University of Technology, Warsaw, Poland, was used. The material used is a dual frequency material, because in a wide temperature range, including room temperature, it shows a change in value, and even in sign, of the anisotropy of the electric permittivity as a function of frequency of the electric field affecting this material. This DFNLC property allows to induce a torque directing the DFNLC director to a position parallel to the direction of the electric field induced in the medium, when the electric field frequency is lower than the cross-over frequency, or a torque directing the director to a position perpendicular to the electric field, when the field frequency is higher than the cross-over frequency. The cross-over frequency is a frequency at which the anisotropy of electric permittivity is equal to zero, see FIG. 3. The cross-over frequency for the DFNLC working mixture is about 10 kHz.

The microcavity can be fabricated using various types of substrates, transparent or non-transparent (back side of the cell for a cell operating in the reflection mode). The DBR mirrors can be replaced with other types of mirrors, or the effect of the wave reflection at the interface between the media can be replaced by suitable selection of the refractive index of the medium filling the cell and the refractive index of the cell wall.

The DFNLC liquid crystal can be replaced with a typical nematic material, smectic material, isotropic liquid that changes its refractive index under the influence of temperature (preferably a mesogenic material at the temperature of the isotropic phase) or electric field, a composite material (preferably a polymeric-liquid crystalline, preferably comprising a material exhibiting the Kerr or an analogous effect, e.g., nanomaterial, e.g., graphene oxide, or graphene oxide decorated with a functional material) that changes its refractive index under the influence of physical fields.

TABLE 1
Selected material data for DFNLC liquid crystalline material.

Material data for a DFNLC (1999C) liquid crystalline material

| | |
|---|---|
| Crystallization temperature T_{cr} (° C.) | <−20 |
| Isotropization temperature T_{Iso} (° C.) | 146.4 |
| Refractive index anisotropy Δn (589 nm) at 23° C. | 0.33 |
| Dielectric constant anisotropy for low (f << f_{c}) frequency of the | 3.19 |
| external electric field Δ∈_{low} (1 kHz) at 23° C. | |
| Dielectric constant anisotropy for high (f >> f_{c}) frequency of the | −2.91 |
| external electric field Δ∈_{high} (1 MHz) at 23° C. | |
| Cross-over frequency f_{c} at 23° C. (kHz) | 8.35 |
| Cross-over frequency f_{c} at 50° C. (kHz) | 79.4 |

### Example 2

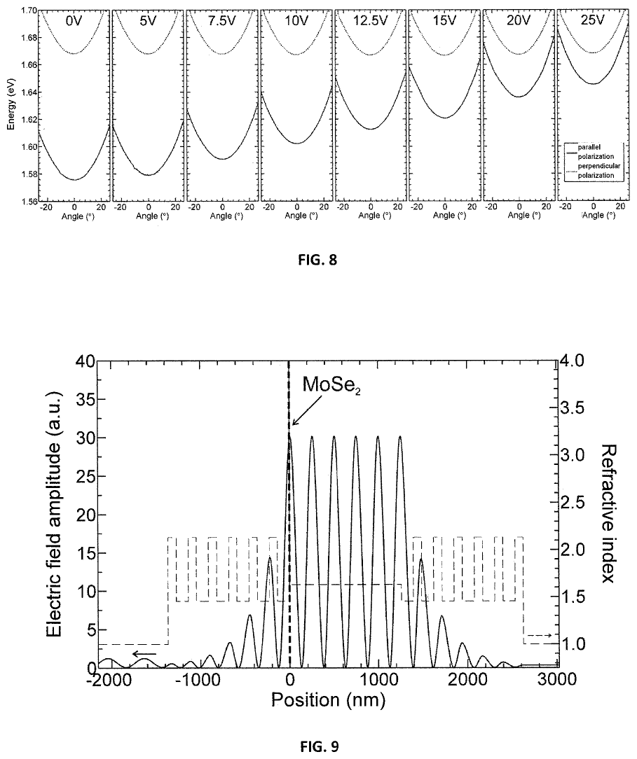

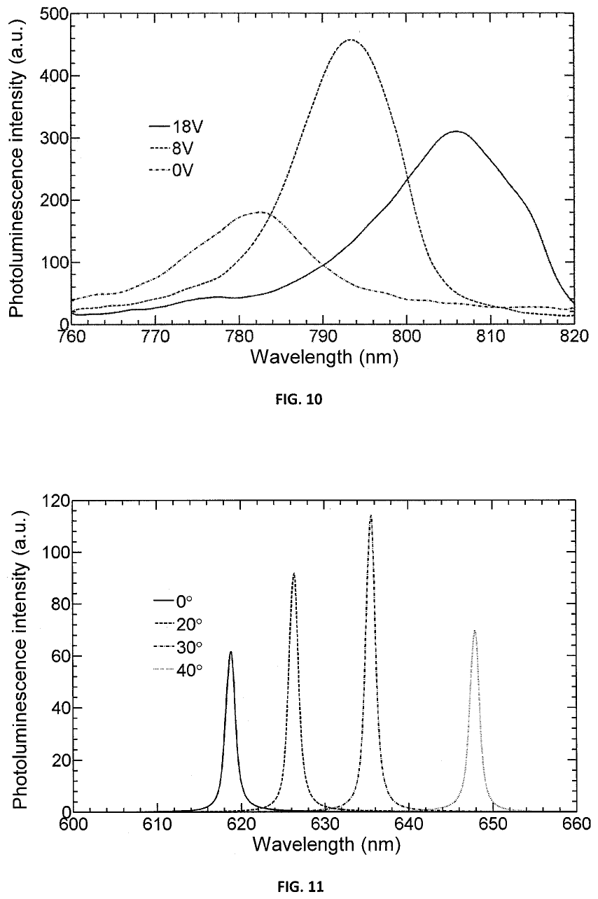

A microcavity was assembled as in Example 1, wherein one Bragg reflector was coated with an emissive material in the form of a single MoSe₂ layer, from both sides covered with a hBN (hexagonal boron nitride) layer with thickness 80 nm. The thicknesses of the hBN layers as well as the SiO₂ and TiO₂ layers were selected so that the MoSe₂ emitter was located at the maximum of the electric field strength of a standing electromagnetic wave in the cavity, as shown in FIG. 9, which illustrates a simulated (with the transfer matrix method) distribution of electric field of 810 nm wavelength inside the microcavity filled with a liquid crystal with an emitter in the form of MoSe₂ monolayers deposited on the surface of one of the mirrors (in the 0 nm position). The cavity thickness was 2.5 lambda (1255 nm for the central wavelength 810 nm and an average refractive index of liquid crystal 1.55). MoSe₂ was excited with 523 nm light. When voltage was applied to microcavity electrodes, the MoSe₂ emission line changed its energy in the range 780-810 nm, as shown in FIG. 10 illustrating the emission intensity from a liquid crystalline microcavity with MoSe₂ monolayers as a function of voltage applied to electrodes of the structure.

### Example 3

A microcavity was assembled as in Example 1 for the wavelength 635 nm, cavity thickness 1220 nm, filled with HT liquid crystal, wherein the liquid crystalline material was additionally doped with a material emitting light as a result of optical excitation. In this case the emitter was CdSe 3.3 nm quantum dots (Lumidot™ 640, from Sigma Aldrich) excited with 532 nm light. When voltage was applied to the microcavity electrodes and upon light excitation, the emission line changed its energy in the range 619-648 nm, as shown in FIG. 11 illustrating the luminescence spectrum from a +/−5 deg range for five different angles of rotation of molecules from the growth axis: 0; 20; 30 and 40 degrees. The microcavity with the central wavelength 635 nm consisted of two Bragg reflectors composed of 5 SiO₂/TiO₂ pairs.

### Example 4

A microcavity was assembled as in Example 1, except that the microcavity was filled with a material exhibiting an analogous effect to the Kerr effect, maintaining the isotropic phase at room temperature, preferably a mesogenic material, for example a nematogen, preferably a liquid referred to as CN, developed and prepared at the Military University of Technology, with the composition as shown in Table 2.

| Compound | CN |
|---|---|
| 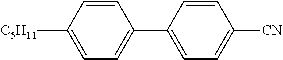 | 60% |
| 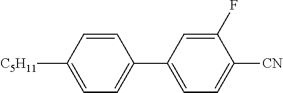 | 40% |
| Clarification temperature [° C.] | 13.7 |

Under the influence of the electric field, CN liquid changes the effective refractive index, which leads to the energy shift of the microcavity optical mode in both linear polarizations and thus the change in the angle of propagation of the monochromatic light transmitted by the sample.

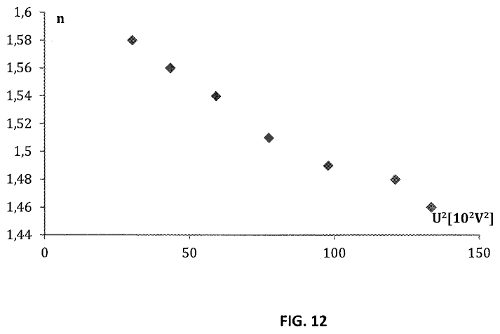

FIG. 12. shows the dependence of the refractive index n for the He—Ne laser wave propagating along the direction of the electric field vector acting on CN liquid. Cavity thickness was 2.5 lambda (1255 nm for the central wavelength 810 nm and an average refractive index of liquid crystal 1.55).

1. An optical microcavity characterised in that it comprises electrodes (12) on substrates (11), wherein the electrodes are comprised (included) in the structure of dielectric or metal mirrors (13), or each of the electrodes has at least one dielectric or metal mirror (13) on it, or the electrodes are semitransparent metal mirrors (13), wherein the mirrors are preferably located at a separation being a multiple of ½ lambda, where lambda is the central wavelength of the cavity mode, the cavity between the mirrors being filled with material (15) that changes the effective refractive index under the influence of external fields, preferably such as electric, magnetic field, thermal and mechanical stress.

2. The optical microcavity according to claim 1 characterised in that the electrodes (12) are transparent for electromagnetic wave, preferably in the visible VIS and/or infrared IR and/or medium wavelength infrared MWIR ranges.

3. The optical microcavity according to claim 1, characterised in that the electrodes (12) are made of such material as indium tin oxide, conductive polymer, metal, or a combination thereof.

4. The optical microcavity according to claim 1, characterised in that the mirrors (13) are Bragg reflectors composed of multiple alternating layers of dielectrics with different refractive indices, and the optical thickness of the layers is ¼ lambda.

5. The optical microcavity according to claim 1, characterised in that the electrodes (12) included in the structure of metal or dielectric mirrors (13) or the dielectric or metal mirrors (13) are located at a separation from ½ lambda to 20 lambda, lambda being the central wavelength of the cavity mode.

6. The optical microcavity according to claim 1, characterised in that the material (15) is a liquid crystalline material in the isotropic phase, or in the nematic phase, or the cholesteric phase, or the blue phase, or the smectic phase, particularly in the SmC* and SmC*A phases, or a material exhibiting a Kerr or an analogous effect, as it is the case for mesogenic materials in the isotropic phase, or a polymeric composite material comprising a liquid crystal, and/or a luminophor, and/or a dye, /or nanoparticles, /or proteins.

7. The optical microcavity according to claim 1, characterised in that the substrate (11) can be transparent or non-transparent.

8. The optical microcavity according to claim 1, characterised in that it has the form of a flat-parallel cell.

9. The optical microcavity according to claim 1, comprising inside an electromagnetic wave emitter, preferably on the surface of one or two mirrors (13), or dissolved or suspended in a material (15) that fills the cell and changes the refractive index under the influence of physical fields, wherein the emitter emits an electromagnetic wave that matches the central wavelength of the cavity mode.

10. The optical microcavity according to claim 9, wherein the emitter of the electromagnetic wave is preferably selected from such as MoSe₂, CdSe, WSe₂, luminescent perovskite, nanodiamond, dye, luminophore or proteins.
